(19) United States
(12) Patent Application Publication
(10) Pub. No.: US 2015/0007877 A1
(43) Pub. Date: Jan. 8, 2015

(54) POLYSILAZANE COATING FOR PHOTOVOLTAIC CELLS

(71) Applicant: GTAT CORPORATION, Merrimack, NH (US)

(72) Inventors: Robert Brainard, Sunnyvale, CA (US); Venkatesan Murali, San Jose, CA (US)

(21) Appl. No.: 14/308,691

(22) Filed: Jun. 18, 2014

Related U.S. Application Data
(60) Provisional application No. 61/843,284, filed on Jul. 5, 2013.

(51) Int. Cl. H01L 31/0216; H01L 31/048

(52) U.S. Cl. CPC H01L 31/02168; H01L 31/048
USPC 136/256; 438/72

(57) ABSTRACT

A method of fabricating a photovoltaic cell, and a device produced by such a method, are described. The method includes providing a semiconductor substrate and electrically coupling an electrically conductive article to a top surface of the semiconductor substrate. An anti-reflective coating is formed over the semiconductor substrate and the electrically conductive article, in which the anti-reflective coating has a plurality of sub-layers. Each of the sub-layers comprises polysilazane and has a different index of refraction from the other sub-layers. A photovoltaic cell is formed from the semiconductor substrate, the electrically conductive article and the anti-reflective coating.

### RELATED APPLICATIONS

This application claims priority to U.S. Provisional Patent Application No. 61/843,284 filed on Jul. 5, 2013, and entitled “Polysilazane Coating for Photovoltaic Cells,” which is hereby incorporated by reference for all purposes.

### BACKGROUND OF THE INVENTION

A solar cell is a device that converts photons into electrical energy. The electrical energy produced by the cell is collected through electrical contacts coupled to the semiconductor material, and is routed through interconnections with other photovoltaic cells in a module. The “standard cell” model of a solar cell has a semiconductor material, used to absorb the incoming solar energy and convert it to electrical energy, placed below an anti-reflective coating (ARC) layer, and above a metal backsheet. Electrical contact is typically made to the semiconductor surface with fire-through paste, which is metal paste that is heated such that the paste diffuses through the ARC layer and contacts the surface of the cell. The paste is generally patterned into a set of fingers and bus bars which will then be soldered with ribbon to other cells to create a module. Another type of solar cell has a semiconductor material sandwiched between transparent conductive oxide layers (TCO's), which are then coated with a final layer of conductive paste that is also configured in a finger/bus bar pattern.

Anti-reflection coating (ARC) layers are commonly used in solar modules to reduce the amount of sunlight reflected from the solar cell surface, thereby increasing the amount of light incident on the semiconductor and increasing the cell conversion efficiency. Silicon nitride is a commonly used ARC material in silicon solar cells, and can be adjusted from its standard refractive index of 2.0 by incorporating oxygen to the film. Multiple ARC layers can improve efficiency gains by engineering the refractive indices of the silicon nitride or silicon oxynitride layers.

### SUMMARY OF THE INVENTION

A method of fabricating a photovoltaic cell, and a device produced by such a method, are described. The method includes providing a semiconductor substrate and electrically coupling an electrically conductive article to a top surface of the semiconductor substrate. An anti-reflective coating is formed over the semiconductor substrate and the electrically conductive article. The anti-reflective coating has a plurality of sub-layers. Each of the sub-layers comprises polysilazane and has a different index of refraction from the other sub-layers. A photovoltaic cell is formed from the semiconductor substrate, the electrically conductive article and the anti-reflective coating.

### BRIEF DESCRIPTION OF THE DRAWINGS

Each of the aspects and embodiments of the invention described herein can be used alone or in combination with one another. The aspects and embodiments will now be described with reference to the attached drawings.

FIG. 1A-1B are representations of polysilazane compositions.

FIG. 2 is a perspective view of a conventional solar cell.

FIG. 3 is a cross-sectional view of a conventional back-contact solar cell.

FIGS. 4A-C show cross-sectional views of a solar cell with an anti-reflective polysilazane coating in some embodiments.

FIG. 5 provides a detailed cross-sectional view of the polysilazane coating of FIG. 4.

FIG. 6 is a cross-sectional view of a solar cell with an anti-reflective polysilazane coating in another embodiment.

FIG. 7 is a cross-sectional view of a solar cell with an anti-reflective polysilazane coating in a further embodiment.

FIG. 8 shows a flowchart for an exemplary method for fabricating a photovoltaic cell with a multi-layer, anti-reflective, polysilazane coating.

FIGS. 9A-9B illustrate top views of exemplary electrical conduits, and FIG. 9C shows a cross-sectional view of the conduit of FIG. 9B.

### DETAILED DESCRIPTION OF THE EMBODIMENTS

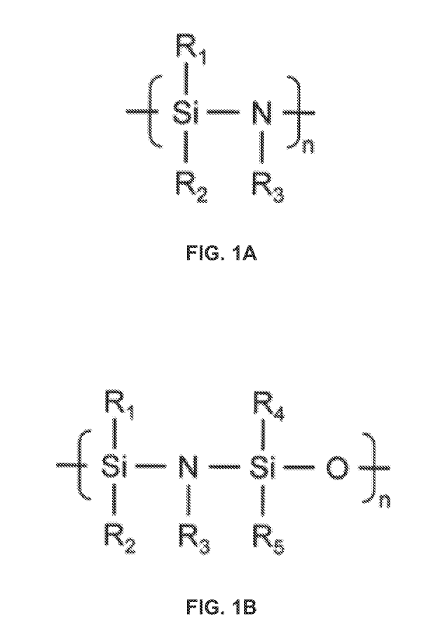

Polysilazanes are a class of polymers that contain silicon-nitrogen linkages in the polymer backbone. Additionally, polysilazanes may further contain oxygen atoms in the polymer backbone, in addition to silicon and nitrogen. Representative structures are shown in FIGS. 1A and 1B, in which R1-R5, which can be the same or different, are side chains including hydrogen, a substituted or unsubstituted alkyl group (such as a methyl, ethyl, propyl, allyl, or vinyl group), or a substituted or unsubstituted aryl group (such as a phenyl or substituted phenyl group) and n represents the number of repeat units in the polymer and is an integer, such as from about 10 to about 1000. Polysilazane-based thin films are used in different industries, such as food packaging and automotive coatings, and offer a variety of properties at a low cost. Described herein is a polysilazane multi-layer anti-reflective coating for solar cells, which can also provide corrosion protection. The composition, formation conditions, and post-synthesis thermal treatment of the polysilazane films may be adjusted using any method known in the art in order to produce a polysilazane having the desired material and chemical properties such as refractive index, optical transparency, and corrosion resistance.

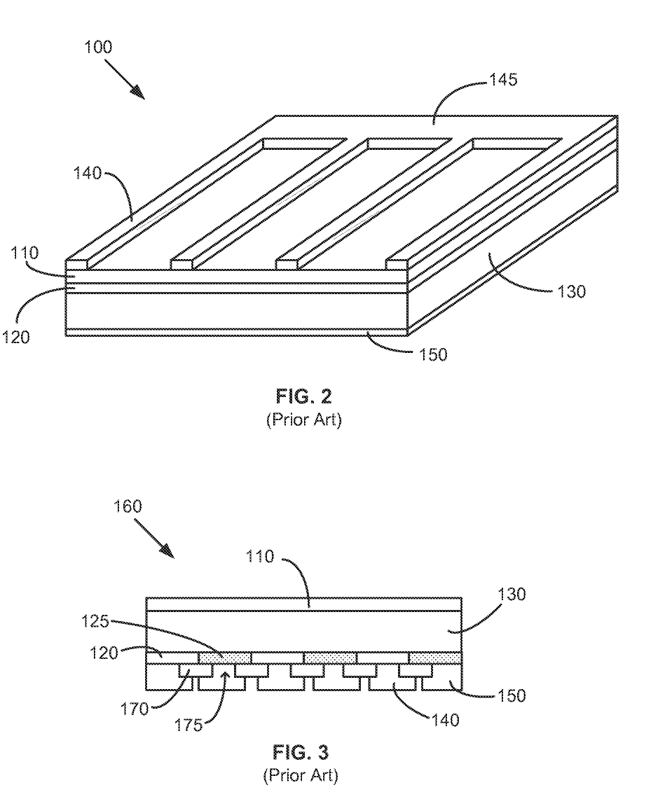

FIG. 2 is a simplified schematic of a conventional solar cell 100 which includes an anti-reflective coating (ARC) layer 110, an emitter 120, a base 130, front contacts 140, and a rear contact layer 150. Emitter 120 and base 130 are semiconductor materials that are doped as p+ or n− regions, and may be referred to together as an active region of a solar cell. Front contacts 140 are typically fired through anti-reflective coating layer 110 in order to make electrical contact with the active region. Incident light enters the solar cell 100 through ARC layer 110, which causes a photocurrent to be created at the junction of the emitter 120 and base 130. The produced electrical current is collected through an electrical circuit connected to front contacts 140 and rear contact 150. A bus bar 145 may connect the front contacts 140, which are shown here as finger elements. Bus bar 145 collects the current from front contacts 140. Bus bar 145 also may be used to provide interconnection between other solar cells by soldering a metal ribbon to the bus bar 145, then stringing the ribbon to an adjacent cell and soldering it to that cell. The assembly of front contacts 140 and bus bar 145 may also be referred to as a metallization layer. In other types of solar cells, a transparent conductive oxide (TCO) layer may be used instead of a dielectric-type ARC layer, to collect electrical current. In a TCO type of cell, metallization in the form of, for example, front contacts 140 and bus bar 145 would be fabricated onto the TCO layer, without the need for firing through, to collect current from the TCO solar cell.

FIG. 3 illustrates a simplified schematic of another type of solar cell 160, in which the electrical contacts are made on the back side, opposite of where light enters. Solar cell 160, also known as an interdigitated back contact cell, includes an ARC layer 110, a base region 130 made of a semiconductor substrate, and doped regions 120 and 125 having opposite polarities from each other (e.g., p-type and n-type). Doped regions 120 and 125 are on the back side of cell 160, opposite of ARC layer 110. A non-conducting layer 170 provides separation between the doped regions 120 and 125, and also completes the role of passivation of the back surface of cell 160. Electrical contacts 140 and 150 are interdigitated with each other and make electrical connections to doped regions 120 and 125, respectively, through holes 175 in the passivating layer 170. The electrical contacts 140 and 150 may present issues such as manufacturing yield losses when forming the contacts onto the cell, high material costs if using silver for the contacts, or degradation of the cell if using copper for the contacts without adding a complicated and expensive barrier layer between the copper contacts and the semiconductor.

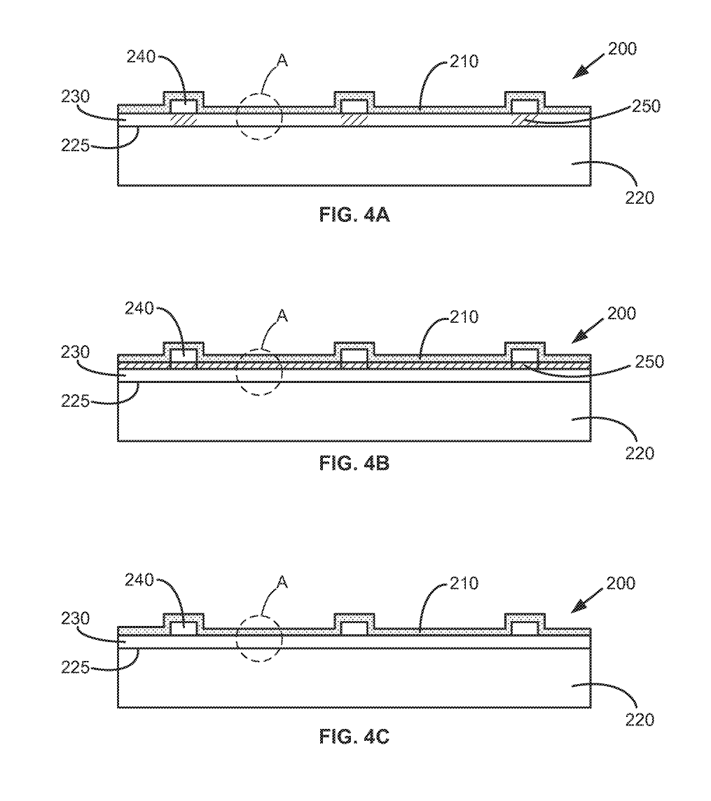

FIGS. 4A-4C show a cross-sectional view of a standard solar cell 200 in some embodiments, in which the cell comprises a polysilazane coating 210 which can be used, for example, as an ARC layer. Solar cell 200 also includes a semiconductor substrate 220, a first layer 230 over a top surface 225 of substrate 220, electrical conduits 240, and, in some embodiments, a second layer 250 between each electrical conduit article 240 and first layer 230. Semiconductor substrate 220 may be, for example, crystalline silicon. First layer 230 may be, for example, silicon nitride (Si₃N₄), a transparent conductive oxide (e.g., indium-tin-oxide), or amorphous silicon, depending on the type of solar cell being used. Silicon nitride as first layer 230 serves as a passivation layer, and also can provide anti-reflection properties. Electrical conduit 240 is an electrically conductive article that collects current from semiconductor substrate 220, and may comprise, for example, a metal such as silver or copper. In some embodiments, conduit 240 may be electroplated or deposited onto cell 200. In other embodiments, conduit 240 may be a pre-fabricated article attached to solar cell 200. For example, conduit 240 may be a free-standing electroformed article fabricated in a mandrel, such as described in Babayan et al., U.S. patent application Ser. No. 13/798,123 entitled “Free-Standing Metallic Article for Semiconductors”, filed on Mar. 13, 2013, which is owned by the assignee of the present application and is hereby incorporated by reference for all purposes.

In some embodiments, second layer 250 is present to assist in electrically coupling conduit 240 to substrate 220. For example, in FIG. 4A second layer 250 may be a fire-through silver paste used with a first layer 230 of silicon nitride. In other examples, second layer 250 may be a silver paste layer used to enhance conductivity with a first layer 230 of TCO as in FIG. 4B. In other embodiments illustrated by FIG. 4C, second layer 250 may be omitted, such as by placing conduit 240 in direct contact with a TCO first layer 230 or an amorphous silicon layer 230. In embodiments where electrical conduit 240 is a pre-fabricated article, the pre-fabricated article may be joined to the photovoltaic cell with, for example, a bonding agent such as solder or electrically conductive adhesive (ECA). In FIG. 4A, the bonding agent (not shown) could be placed between pre-fabricated conduit 240 and second layer 250, which would be a fire-through paste. In FIG. 4B, the second layer 250 may be a silver conduit line, and the bonding agent would be applied between second layer 250 and the conduit 240. In a further embodiment where first layer 230 is conductive, such as a TCO or amorphous silicon in FIG. 4C, the conduit 240 can be attached directly to first layer 230 by applying the bonding agent between conduit 240 and first layer 230.

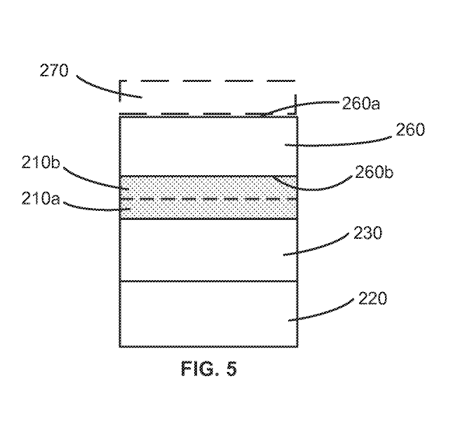

In certain embodiments, a cover element is placed over an anti-reflective coating. A first layer is deposited on a semiconductor substrate prior to forming the anti-reflective coating. The first layer has a first index of refraction and the cover element has a second index of refraction, and polysilazane sub-layers of the anti-reflective coating have indices of refraction that provide a graded change from the first index of refraction to the second index of refraction. FIG. 5 shows an exemplary detailed view of area A of FIG. 4A-4C, with the addition of a front cover element 260 for the solar cell 200 in this embodiment. Layer 250 of FIG. 4B has been omitted for clarity. Front cover 260 is a transparent sheet, such as glass or plastic, placed over and/or laminated to the solar cell 200 to protect it from environmental conditions. In FIG. 5, polysilazane layer 210 is seen to include multiple sub-layers 210a and 210b, which are both polysilazanes having different structures and are customized to produce a graded refraction index, thus reducing reflective losses. Sub-layers 210a and 210b form a dual-layer ARC in this embodiment; however, in other embodiments, more than two sub-layers may be included. The sub-layers 210a and 210b each have an index of refraction that in one embodiment is tailored by choosing a specific polysilazane structure (side chain and proportion of silicon, nitrogen, and optionally oxygen) to achieve the desired value. In one embodiment, first layer 230 is Si₃N₄ with an index of refraction of approximately 2, and the cover element 260 is glass with an index of refraction of approximately 1.5. To create a graded change between the silicon nitride layer 230 and glass cover element 260, sub-layer 210a may be chosen with an index of refraction n_{A} of, for example, 1.5<n_{A}<1.75 and sub-layer 210b may be chosen with an index of refraction n_{B} of, for example, 1.75<n_{B}<2.0. Other intermediate ranges for n_{A} and n_{B} are possible. The graded series of refractive indices that are intermediate to the neighboring layers reduces optical transmission losses and improves conversion efficiency. In other embodiments, the first layer 230 may be omitted, and n_{A} and n_{B} can be chosen to provide a graded change in refractive index between, for example, 3.5 for the silicon substrate 220 and 1.5 for the cover element 260. In further embodiments, the cover element 260 is placed over the anti-reflective coating 210a/b, where the cover element 260 has a bottom surface 260b and a top surface 260a, and where the bottom surface 260b faces the anti-reflective coating 210a/b. An outer anti-reflective coating 270 comprising polysilazane is formed on the top surface 260a of the cover element 260.

In another aspect, the polysilazane coating may reduce metal corrosion and electromigration in a solar cell. As the solar industry continually seeks to lower the cost of materials, copper is one material that is being used to replace expensive silver contacts that are commonly used. Copper has suitable mechanical and electrical properties, is less expensive than silver, and is easily integrated into silicon solar cell architectures. However, copper metal contacts present some challenges for photovoltaic cell design. Copper is easily oxidized in wet environments, which can cause reliability issues over the lifespan of a solar module. In addition, copper has a high diffusion coefficient in silicon, even at room temperature. When copper atoms diffuse, they form deep level traps in the host silicon, which can decrease performance of the solar cell. Although complex and expensive integration schemes have been devised to address copper electromigration in integrated circuits, such schemes are impractical in the solar industry, which is more sensitive to cost.

As shown in FIGS. 4A-4C, the polysilazane layer 210 may be used to coat all exposed surfaces of the electrical conduit 240. That is, polysilazane layer 210 may be an anti-reflective coating that covers all exposed areas of the electrically conductive article. The anti-reflective coating is located over the electrically conductive article and the top surface of the semiconductor substrate, where the anti-reflective coating comprises a plurality of sub-layers, each of the sub-layers comprising polysilazane and having different indices of refraction from each other. Coating all exposed surfaces protects the conduit 240 from moisture that may seep into the solar cell 200, which can cause corrosion. The protection may also reduce the risk of electromigration into the semiconductor substrate. Although a copper conduit 240 may be coated or plated with barrier materials such as nickel, it is possible that some gaps in the barrier coating may exist. For example, the barrier coating may not form at locations at which the conduit 240 is being secured by a tool or mandrel during the plating process. Thus, the polysilazane layer 210 provides an additional isolation barrier for the electrical conduit 240, which can be lower cost than conventional barrier layers. Polysilazane may be applied as a corrosion or electromigration barrier in back contact cells (FIG. 2) as well as front contact cells, such as those of FIGS. 4A-4C.

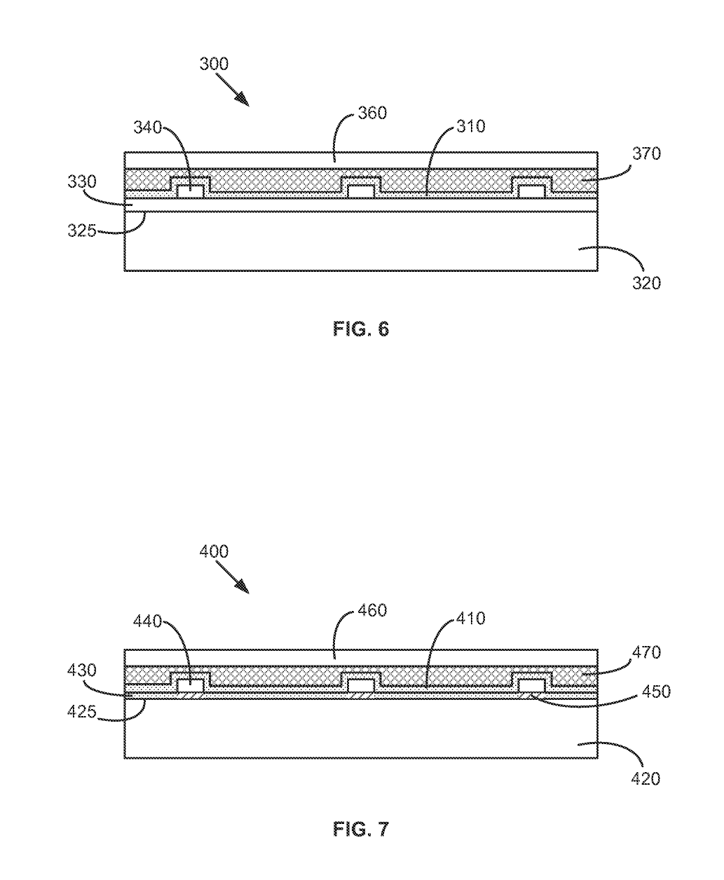

In FIG. 6, another embodiment of a solar cell 300 is shown in which solar cell includes an encapsulant 370. Solar cell 300 has similar components to those of FIGS. 4A-4C, including a multi-layer polysilazane coating 310, a semiconductor substrate 320, a first layer 330 on a top surface 325 of substrate 320, and electrical conduit 340. The multi-layer coating 310 comprises a plurality of polysilazane layers to provide graded refractive properties, as described in more detail above. In this embodiment, a second layer is omitted so that conduit 340 is in direct contact with first layer 330, such as in the case of a TCO or heterojunction cell. However, a second layer, such as a silver fire-through paste as shown in FIG. 4A, between electrical conduit 340 and first layer 330 may be included in other embodiments. In FIG. 6 a cover element 360 is placed over the entire solar cell, and an encapsulant 370 fills the space between the cover element 360 and the remaining portions of the cell 300. Encapsulant 370 may be a solar encapsulant material known in the art, such as an ethylene vinyl acetate (EVA), a thermoplastic polyolefin (TPO) or a polyvinyl butyral (PVB). Some encapsulants are acid-producing, such as ethylene vinyl acetate (EVA) which decomposes over time and upon exposure to water, thereby generating acetic acid. This acid poses a corrosion risk to copper. In the embodiment of FIG. 6, polysilazane layer 310 provides a barrier for the copper conduit 340 against acid attack in addition to serving as an anti-reflective coating. The polysilazane layer also provides a protective coating at a lower cost than methods typically used in the semiconductor industry. Polysilazane layer 310 may have the indices of its sub-layers designed to provide a graded change between first layer 330 and encapsulant 370, as described in relation to FIG. 5.

FIG. 7 shows yet another embodiment in which a solar cell 400 comprises a polysilazane as the first layer 430 instead of a silicon nitride or material. Solar cell 400 includes a polysilazane coating 410, a semiconductor substrate 420, first layer 430 on a top surface 425 of substrate 420, an electrical conduit 440, a second layer 450, a cover element 460 and an encapsulant 470. In this embodiment, first layer 430 also comprises a polysilazane, wherein second layer 450 may be fired through the polysilazane layer 430. The additional polysilazane layer 410 is coated over the first layer 430 and over the electrical conduits 440. Thus the anti-reflective coating for the solar cell 400 is a multi-layer coating comprising polysilazane first layer 430 as one sub-layer, along with one or more sub-layers within polysilazane coating 410. The first polysilazane layer 430 may provide passivation in addition to anti-reflection properties.

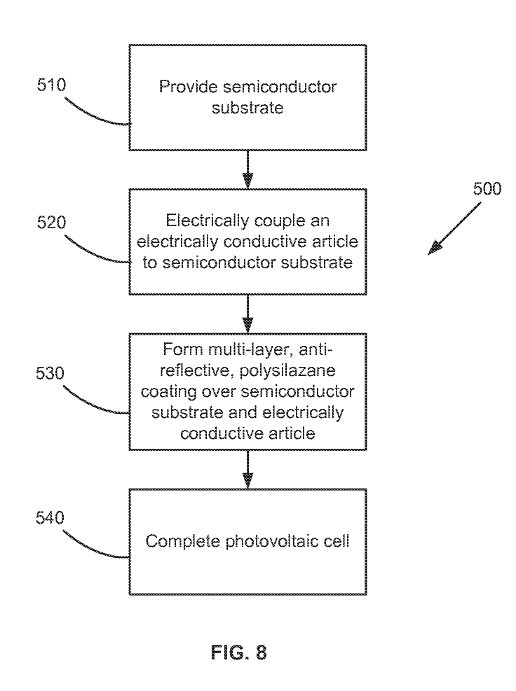

FIG. 8 provides a flowchart 500 of an exemplary method for applying a multi-layer polysilazane coating in photovoltaic cells. In step 510, a semiconductor substrate having a top surface is provided. The substrate may be crystalline silicon, or other suitable material appropriate for the type of solar cell being produced. In step 520, an electrically conductive article is electrically coupled to the semiconductor substrate. As described above, the electrically conductive article may be a free-standing piece or may be deposited or formed onto the substrate. The article may be electrically coupled to a top surface of the semiconductor substrate by, for example, soldering the article onto the substrate, by forming the article on the substrate such as by electroplating and etching, or by use of a fire-through paste. One or more layers may be included between the electrically conductive article and the semiconductor substrate, including but not limited to silicon nitride with fire-through pastes, transparent conductive oxides, and amorphous silicon. In some embodiments, a first layer—such as a silicon nitride, a transparent conductive oxide or an amorphous silicon—may be deposited on the semiconductor substrate prior to forming the anti-reflective coating, where the electrically conductive article is electrically coupled to the semiconductor substrate through the first layer.

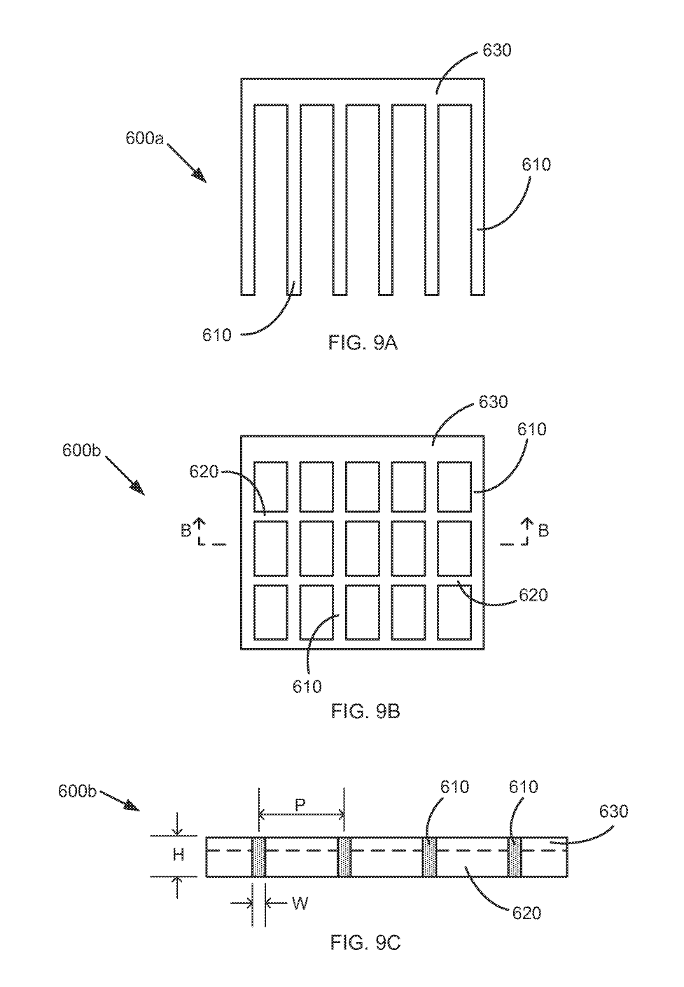

In step 530, a polysilazane coating is deposited over the top surface of the semiconductor substrate and the electrically coupled conductive article. An anti-reflective layer is formed over the electrically conductive article and the top surface of the semiconductor substrate, where the anti-reflective coating includes a plurality of sub-layers. Each of the sub-layers comprises a polysilazane, where the sub-layers have different indices of refraction from each other. In some embodiments, the index of refraction of each sub-layer is the value as measured after curing. Polysilazane films are typically prepared from liquid precursor chemicals that are deposited on a target substrate, dried and cured at elevated temperatures to form a stable polymer film. In some embodiments, a multi-polysilazane ARC is deposited over conventional silver fingers. To allow for electrical connection of bus bars, the polysilazane is masked or removed in the bus bar areas. In other embodiments, an electroformed conduit with integral bus bars may be used, as shall be described in relation to FIGS. 9A-9C. For these electroformed conduits, masking or removal of the polysilazane in the bus bar regions may not be required. A multi-layer polysilazane ARC as disclosed herein provides a low-cost coating for the cost-sensitive photovoltaic industry, by being able to be applied with relatively low-cost methods and at relatively low temperatures. For example, annealing an inorganic polysilazane film (where R=hydrogen) in an oxygen-containing atmosphere results in a layer with a refractive index of 1.46, while annealing the same film in an inert or ammonia-containing environment results in a layer with a refractive index of around 2. In one embodiment, a first polysilazane sub-layer is applied, then a second polysilazane sub-layer and any subsequent sub-layers (some of which may or may not include polysilazane) are formed over the first sub-layer. The polysilazane layers may be applied by methods including, but not limited to, spraying, dip coating, spinning, micro-jet dispensing. The particular method may be chosen depending on factors such as the thicknesses desired, or the level of thickness control required. Thicknesses of the total multi-layer polysilazane stack may be in the range of, for example, 500-1500 angstroms. The thicknesses of individual sub-layers will depend on the wavelength of light and specific index of refraction desired for that sub-layer.

In one embodiment of step 530, a first layer may be applied to a photovoltaic substrate, covering an electrical conduit, and heated at a low temperature to drive off solvents. Then a second sub-layer may be applied over the first sub-layer, and both polysilazane sub-layers heated at a higher temperature to invoke the final curing. Heating or baking steps may be performed, for example, in an oven, on a hot plate, or under heat lamps. In some embodiments, a conveyor may be utilized to process photovoltaic cells through a series of heat lamps or through an oven. Specific process parameters for the coating and heating steps may be optimized to balance various product and manufacturing factors, including: final optical properties of the coating, chemical resistance of the cured product to acid (e.g. from encapsulant), longevity of the final coating (e.g. on the order of 25 years for solar modules), desired coating thicknesses, desired accuracy of thickness control, manufacturing costs, and temperature tolerance of other materials in the assembly. In some embodiments, the cure temperature of the polysilazane sub-layer may be designed to be low enough such that it does not impact other components of the photovoltaic cell such as the copper conduit or the attachment material—e.g., solder or ECA which can melt or decompose at a few hundred degrees Celsius. A low curing temperature is also beneficial in that it does not require high-temperature (and thus more costly) curing equipment.

Because the curing conditions of polysilazane affect the material properties, in some embodiments the cure temperature, humidity, and/or gas environment may be chosen to adjust the final index of refraction and other properties of the polysilazane. For example, one cure temperature may be chosen for the entire polysilazane stack, with all the polysilazane sub-layers being cured at the same time. In another example, different cure temperatures may be used for each sub-layer. That is, a first sub-layer may be cured at a first temperature, and then a second sub-layer may be deposited over the first sub-layer and cured at a second temperature. In these various embodiments, the curing temperature may be less than 300° C., such as less than 200° C., or between 150-200° C. Some polysilazanes may be designed to be cured at temperatures as low as approximately room temperature. The combination of temperature and polysilazane composition may be determined based on temperature limits of other components within the photovoltaic cell. In some embodiments, the humidity may range between, for example, 90%-100% to achieve a desired refractive index. In some embodiments, an outer anti-reflective coating comprising polysilazane is formed on the top surface of the cover element, which may be, for example, glass.

In step 540 of FIG. 8, a photovoltaic cell is completed from the assembly. The photovoltaic cell is formed from the semiconductor substrate, the electrically conductive article and the anti-reflective coating. This may include applying an encapsulant over the cell, placing a cover element over the assembly, and preparing interconnection elements to connect the cell to other cells in a module. In some embodiments, step 540 may include encapsulating the photovoltaic cell with an acid-producing encapsulant. Because the polysilazane completely covers the electrically conductive article for corrosion and electromigration protection, any electrical connections to the article should be completed prior to coating, or be made in areas in which exposed metal components will not lead to potential cell contamination.

FIGS. 9A-9C illustrate embodiments of electroformed electrical conduits produced in electroforming mandrels, as disclosed in Babayan et al., U.S. patent application Ser. No. 13/798,123, and that may be used in the solar cells of the present disclosure. FIGS. 9A-9B are top views of exemplary metal conduits 600a and 600b that may comprise, for example, copper or a nickel-coated copper. Metal layers 600a and 600b include electroformed elements embodied here as substantially parallel fingers 610, which have been formed by substantially parallel grooves in an electrically conductive mandrel. Metal layer 600b also includes electroformed elements embodied here as horizontal fingers 620 that intersect vertical fingers 610, where the fingers 610 and 620 intersect at approximately a perpendicular angle. In other embodiments, fingers 610 and 620 may intersect at other angles, while still forming a continuous grid or mesh pattern. Conduits 600a and 600b also include a frame element 630 which may serve as a bus bar to collect current from the fingers 610 and 620. Having a bus bar integrally formed as part of the metallic article can provide manufacturing improvements. In present high-volume methods of solar module production, cell connections are often achieved by manually soldering metal ribbons to the cells. This commonly results in broken or damaged cells due to manual handling and stress imparted on the cells by the solder ribbons. In addition, the manual soldering process results in high labor-related production costs. Thus, having a bus bar or ribbon already formed and connected to the metallization layer, as is possible with an electroformed metallic articles, enables low-cost, automated manufacturing methods. Because the elements 610, 620 and 630 are all integrally formed, it is possible to deposit a polysilazane coating over the article 600a or 600b without the need for making subsequent electrical connections between the fingers 610, 620 or bus bar 630. The relatively low cure temperatures of polysilazane also enable the coating to be compatible with soldered components, such that the coating may be applied and cured before or after soldering.

Frame element 630 may also provide mechanical stability such that metal conduits 600a and 600b are unitary, free-standing articles when removed from a mandrel. That is, the metal conduits 600a and 600b are unitary in that they are a single component, with the fingers 610 and 620 remaining connected, when apart from a photovoltaic cell or other semiconductor assembly. Frame element 630 may furthermore assist in maintaining spacing and alignment between finger elements 610 and 620 for when they are to be attached to a photovoltaic cell. Frame element 630 is shown in FIGS. 9A-9B as extending across one edge of metal conduits 600a and 600b. However, in other embodiments, a frame element may extend only partially across one edge, or may border more than one edge, or may be configured as one or more tabs on an edge, or may reside within the grid itself. Furthermore, frame element may be electroformed at the same time as the fingers 610 and 620, or in other embodiments may be electroformed in a separate step, after fingers 610 and 620 have been formed.

FIG. 9C shows a cross-section of metal conduit 600b taken at section B-B of FIG. 9B. The fingers 610 and 620 have a height ‘H’ and width ‘W’, where the height-to-width ratio defines an aspect ratio. By using an electroforming mandrel to form the metal conduits 600a and 600b, the electroformed metallic segments can be tailored for photovoltaic applications, such as to reduce shading. Fingers 610 in this embodiment are shown in as having aspect ratios greater than 1, such as about 1 to about 5, and such as approximately 2 in this figure. Having a cross-sectional height greater than the width reduces the shading impact of metal conduit 600b on a photovoltaic cell. In various embodiments, only a portion of the fingers 610 and 620 may have an aspect ratio greater than 1, or a majority of the fingers 610 and 620 may have an aspect ratio greater than 1, or all of the fingers 610 and 620 may have an aspect ratio greater than 1. Height ‘H’ of fingers 610 may range from, for example, about 5 microns to about 200 microns, or about 10 microns to about 300 microns. Width ‘W’ of fingers 610 may range from, for example, about 10 microns to about 5 mm, such as about 10 microns to about 150 microns. The distance between parallel fingers 610 has a pitch ‘P’, measured between the centerline of each finger. In some embodiments the pitch may range, for example, between about 1 mm and about 25 mm. In FIGS. 9B and 9C, the fingers 610 and 620 have different widths and pitches, but are approximately equivalent in height. In other embodiments, the fingers 610 and 620 may have different widths, heights and pitches as each other, or may have some characteristics that are the same, or may have all the characteristics the same. The values may be chosen according to factors such as the size of the photovoltaic cell, the shading amount for a desired efficiency, or whether the metallic article is to be coupled to the front or rear of the cell. In some embodiments, fingers 610 may have a pitch between about 0.5 mm and about 6 mm and fingers 620 may have a pitch between about 1.5 mm and about 25 mm. Fingers 610 and 620 are formed in mandrels having grooves that are substantially the same shape and spacing as fingers 610 and 620. Frame element 630 may have the same height as the fingers 610 and 620, or may be a thinner piece as indicated by the dashed line in FIG. 9C. In other embodiments, frame element 630 may be formed on above finger elements 610 and 620.

FIG. 9C also shows that fingers 610 and 620 may be substantially coplanar with each other, in that the fingers 610 and fingers 620 have a majority of their cross-sectional areas that overlap each other. Compared to conventional meshes that are woven over and under each other, a coplanar grid as depicted in FIG. 9C can provide a lower profile than overlapping circular wires of the same cross-sectional area. The intersecting, coplanar lines of metal layer 600b are also formed integrally with each other during the electroforming process, which provides further robustness to the free-standing article of metal layer 600b. That is, the integral elements are formed as one piece and not joined together from separate components.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. A method of fabricating a photovoltaic cell, the method comprising:
providing a semiconductor substrate having a top surface;
electrically coupling an electrically conductive article to the top surface of the semiconductor substrate;
forming an anti-reflective coating over the electrically conductive article and the top surface of the semiconductor substrate, wherein the anti-reflective coating comprises a plurality of sub-layers, wherein each of the sub-layers comprises a polysilazane, and wherein the sub-layers have different indices of refraction from each other; and
forming a photovoltaic cell from the semiconductor substrate, the electrically conductive article and the anti-reflective coating.

2. The method of claim 1 wherein the polysilazane comprises the structure: 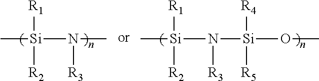
wherein R₁-R₅, which can be the same or different, represent a hydrogen, a substituted or unsubstituted alkyl group, or a substituted or unsubstituted aryl group side chain, and wherein n is an integer from 10 to 1000.

3. The method of claim 2 wherein the side chain is a methyl, ethyl, vinyl, or allyl side chain.

4. The method of claim 1 further comprising depositing a first layer on the semiconductor substrate prior to forming the anti-reflective coating, and wherein the electrically conductive article is electrically coupled to the semiconductor substrate through the first layer.

5. The method of claim 4 wherein the first layer comprises silicon nitride, a transparent conductive oxide or an amorphous silicon.

6. The method of claim 4 further comprising placing a second layer between the electrically conductive article and the first layer, wherein the second layer comprises silver.

7. The method of claim 4 further comprising placing a cover element over the anti-reflective coating, wherein the first layer has a first index of refraction and the cover element has a second index of refraction, and wherein the sub-layers of the anti-reflective coating have indices of refraction that provide a graded change from the first index of refraction to the second index of refraction.

8. The method of claim 7 wherein the cover element comprises glass.

9. The method of claim 1 wherein the anti-reflective coating covers all exposed areas of the electrically conductive article.

10. The method of claim 1 wherein the index of refraction of each sub-layer is after curing.

11. The method of claim 1 further comprising placing a cover element over the anti-reflective coating, wherein the cover element has a bottom surface and a top surface, wherein the bottom surface faces the anti-reflective coating; and
wherein the method further comprises forming an outer anti-reflective coating comprising polysilazane on the top surface of the cover element.

12. The method of claim 1 wherein the electrically conductive article is an electroformed article.

13. The method of claim 1 wherein the electrically conductive article comprises copper.

14. The method of claim 1 further comprising encapsulating the photovoltaic cell with an acid-producing encapsulant.

15. The method of claim 14 wherein the acid-producing encapsulant comprises ethylene vinyl acetate.

16. A photovoltaic cell comprising:
a semiconductor substrate having a top surface;
an electrically conductive article being electrically coupled to the top surface of the semiconductor substrate; and
an anti-reflective coating located over the electrically conductive article and the top surface of the semiconductor substrate, wherein the anti-reflective coating comprises a plurality of sub-layers, wherein each of the sub-layers comprises polysilazane, and wherein the sub-layers have different indices of refraction from each other.

17. The photovoltaic cell of claim 16 wherein the polysilazane comprises the structure: 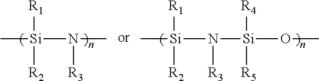
wherein R¹-R⁵, which can be the same or different, represent a hydrogen, a substituted or unsubstituted alkyl group, or a substituted or unsubstituted aryl group side chain; and wherein n is an integer from 10 to 1000.

18. The photovoltaic cell of claim 17 wherein the side chain is a methyl, ethyl, vinyl, or allyl side chain.

19. The photovoltaic cell of claim 16 further comprising a first layer between the semiconductor substrate and the anti-reflective coating, wherein the electrically conductive article is electrically coupled to the semiconductor substrate through the first layer.

20. The photovoltaic cell of claim 19 wherein the first layer comprises silicon nitride, a transparent conductive oxide or an amorphous silicon.

21. The photovoltaic cell of claim 19 further comprising a second layer between the electrically conductive article and the first layer, wherein the second layer comprises silver.

22. The photovoltaic cell of claim 19 further comprising a cover element over the anti-reflective coating, wherein the first layer has a first index of refraction and the cover element has a second index of refraction, and wherein the sub-layers of the anti-reflective coating have indices of refraction that provide a graded change from the first index of refraction to the second index of refraction.

23. The photovoltaic cell of claim 22 wherein the cover element comprises glass.

24. The photovoltaic cell of claim 16 wherein the anti-reflective coating covers all exposed areas of the electrically conductive article.

25. The photovoltaic cell of claim 16 wherein the index of refraction of each sub-layer is after curing.

26. The photovoltaic cell of claim 16 further comprising:
a cover element over the anti-reflective coating, wherein the cover element has a bottom surface and a top surface, wherein the bottom surface faces the anti-reflective coating; and
an outer anti-reflective coating comprising polysilazane on the top surface of the cover element.

27. The photovoltaic cell of claim 16 wherein the electrically conductive article is an electroformed article.

28. The photovoltaic cell of claim 16 wherein the electrically conductive article comprises copper.

29. The photovoltaic cell of claim 16 further comprising an acid-producing encapsulant encapsulating the photovoltaic cell.

30. The photovoltaic cell of claim 29 wherein the acid-producing encapsulant comprises ethylene vinyl acetate.
